(19) United States
(12) Patent Application Publication
(10) Pub. No.: US 2013/0032091 A1
(43) Pub. Date: Feb. 7, 2013

(54) CLEANING METHOD OF FILM FORMING DEVICE AND SEMICONDUCTOR MANUFACTURING APPARATUS

(71) Applicant: Masahiro YOKOGAWA, Osaka-shi (JP)

(72) Inventor: Masahiro YOKOGAWA, Osaka-shi (JP)

(21) Appl. No.: 13/565,014

(22) Filed: Aug. 2, 2012

(30) Foreign Application Priority Data
Aug. 2, 2011 (JP) 2011-169445

(51) Int. Cl. C23C 16/50; B08B 9/00; B08B 7/04; C23C 16/52

(52) U.S. Cl. 118/712; 118/723 R; 134/22.1; 134/18

(57) ABSTRACT

A cleaning method of a film forming device capable of suppressing generation of static electricity is provided. The cleaning method of the film forming device includes the steps of humidifying surroundings of the film forming device; opening said film forming device to an atmosphere; and removing a deposit inside said film forming device.

This nonprovisional application is based on Japanese Patent Application No. 2011-169445 filed with the Japan Patent Office on Aug. 2, 2011, the entire contents of which are hereby incorporated by reference.

### BACKGROUND OF THE INVENTION

1. Field of the Invention

The present invention relates to a cleaning method of a film forming device as well as a semiconductor manufacturing apparatus provided with the film forming device.

2. Description of the Background Art

In a method of manufacturing semiconductor devices such as liquid-crystal display devices or thin-film solar cells, a silicon-contained thin film may be formed on a substrate. For example, a plasma CVD (Chemical Vapor Deposition) device performs this kind of film formation. When the plasma CVD device performs the film forming processing, a film forming material adheres to components other than the substrate in a film forming chamber of the film forming device as well as an inner wall of a vacuum container and exhaust piping. In particular, the film forming material adhering to a portion remote from a plasma discharging region does not form a uniform film but forms a powder-like adhering material. For example, in a plasma CVD device forming a silicon-contained semiconductor film, a silicon-contained adhering material such as polysilane that is produced by solidifying silane that is a process gas by plasma discharge is deposited in the powder-like form.

When an amount of deposited polysilane in a chamber increases with repetition of the film forming processing, the polysilane in the chamber takes a form of fine powder, which may cause such adverse effects that the powder located on the substrate becomes a factor of failure and a large amount of polysilane powder closes the exhaust piping. Accordingly, it is necessary to perform periodically a cleaning operation of opening the vacuum container of the plasma CVD device to an atmosphere and removing the deposited polysilane.

For cleaning the film forming device, there have been disclosed cleaning methods that remove the polysilane deposited in the chamber by etching processing, and particularly plasma cleaning methods that can execute the cleaning without performing atmospheric opening (see, e.g., Japanese Patent Laying-Open No. 6-326034). Also, such techniques have been disclosed that isolate a transportation tank of a film forming device from a processing tank, and clean the inside of the processing tank by opening it to the atmosphere (see, e.g., Japanese Patent Laying-Open No. 7-283099).

The cleaning method disclosed in Japanese Patent Laying-Open No. 6-326034 can clean the inside of the chamber without opening it to the atmosphere. However, many structures such as electrodes and power introduction lines as well as gas piping and cooling pipes are present inside the plasma CVD device. Therefore, it is practically difficult to perform the cleaning that can entirely remove deposited films in the whole inside of the device. Therefore, even the cleaning method in Japanese Patent Laying-Open No. 6-326034 suffers from a problem that powder of the deposit that cannot be completely removed remains in the chamber, and particularly the powder of the deposit remains in the exhaust piping remote from the plasma discharging region.

Accordingly, as disclosed in Japanese Patent Laying-Open No. 7-283099, it is necessary to perform the cleaning operation of periodically opening the vacuum container of the plasma CVD device to the atmosphere and removing the deposited polysilane.

When the vacuum container of the plasma CVD device is opened to the atmosphere and the cleaning is performed, and particularly when deposited fine powder adhering to side walls and exhaust piping are removed with a brush or the like, the fine powder rises into and suspends in the atmosphere. The inner space of the exhaust piping is small and the concentration of the suspending powder therein is particularly high. When an action in the cleaning operation or the like generates static electricity in an environment where the concentration of the suspending fine powder is high, a spark caused by such static electricity may cause a reaction between the fine powder and oxygen to generate heat.

Accordingly, such measures for improving safety by suppressing generation of the static electricity have been employed that ground a cleaning worker through electrically conductive shoes, a grounding band or the like during the cleaning, or that employ a material suppressing or restricting generation of the static electricity as a material of a cleaning tool such as a brush or a scoop. However, the technique for suppressing generation of the static electricity during the cleaning is susceptible to further improvement, and a technique that can prevent generation of the static electricity more reliably has been demanded.

### SUMMARY OF THE INVENTION

A major object of the invention is to provide a cleaning method of a film forming device that can suppress generation of static electricity during cleaning. Another object of the invention is to provide a semiconductor manufacturing apparatus that can suppress generation of static electricity during cleaning of a film forming device.

A cleaning method of a film forming device according to the invention includes the steps of humidifying surroundings of the film forming device; opening the film forming device to an atmosphere; and removing a deposit inside the film forming device.

Preferably, in the above method, the step of humidifying humidifies the surroundings of the film forming device to an absolute humidity of 11.5 g/m³ or more.

Preferably, the above method further includes the steps of measuring a humidity of the surroundings of the film forming device; and determining whether the surroundings of the film forming device have the absolute humidity of 11.5 g/m³ or more, or not. When it is determined in the step of determining that the surroundings of the film forming device have the absolute humidity smaller than 11.5 g/m³, the opening of the film forming device to the atmosphere is inhibited. When it is determined in the step of determining that the surroundings of the film forming device have the absolute humidity equal to 11.5 g/m³ or more, the opening of the film forming device to the atmosphere is allowed.

A semiconductor manufacturing apparatus according to the invention includes a film forming device; and a humidifier arranged outside the film forming device for humidifying surroundings of the film forming device.

Preferably, in the above semiconductor manufacturing apparatus, the film forming device is provided with an opening, the semiconductor manufacturing apparatus further includes an openable and closable open/close door capable of opening and closing the opening, and the humidifier humidifies the surroundings of the film forming device when the open/close door opens to open the opening.

Preferably, the above semiconductor manufacturing apparatus further includes a partition for defining a space surrounding the film forming device, and the humidifier is arranged in the space defined by the partition and is located on a side neighboring to the opening.

Preferably, the semiconductor manufacturing apparatus includes a humidity sensor for measuring a humidity around the film forming device.

Preferably, the semiconductor manufacturing apparatus includes a control unit for controlling an operation of the semiconductor manufacturing apparatus, and the control unit operates the humidifier to humidify the surroundings of the film forming device and to attain an absolute humidity of 11.5 g/m³ or more.

Preferably, the semiconductor manufacturing apparatus includes an alarming unit for giving an operation instruction to an operator operating the semiconductor manufacturing apparatus.

The cleaning method of the film forming device according to the invention can suppress generation of the static electricity during the cleaning.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 schematically shows a plasma CVD device according to an embodiment.

FIG. 2 schematically shows a semiconductor manufacturing apparatus including the plasma CVD device shown in FIG. 1.

FIG. 3 is a block diagram schematically showing a control device controlling an operation of the semiconductor manufacturing apparatus.

FIG. 4 is a flowchart showing various steps in a cleaning method of the plasma CVD device.

### DESCRIPTION OF THE PREFERRED EMBODIMENTS

Embodiments of the invention will now be described with reference to the drawings. In the following description, the same or corresponding portions bear the same reference numbers, and description thereof is not repeated.

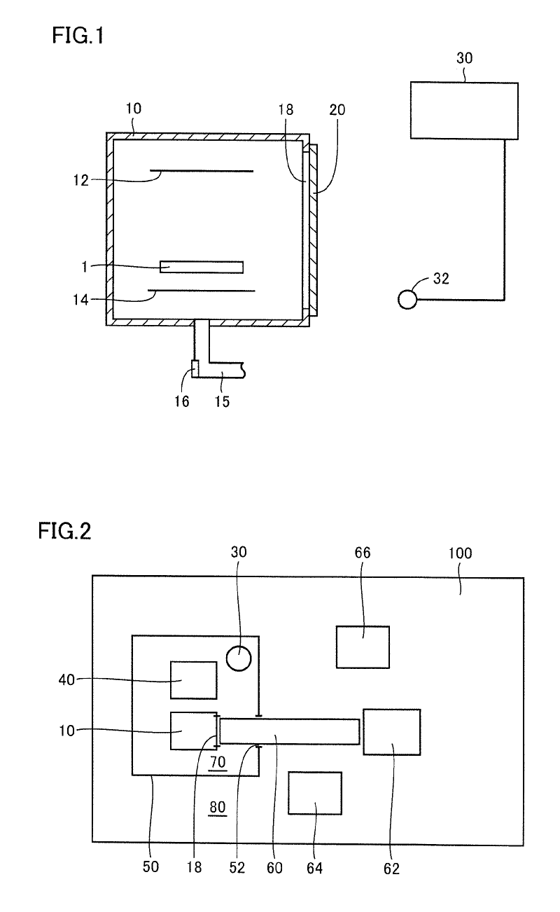

As shown in FIG. 1, a plasma CVD device 10 is an example of a film forming device for performing processing of forming a thin film on a main surface of a substrate 1 that is disposed inside a vacuum container. Plasma CVD device 10 includes an upper electrode 12 arranged above substrate 1 and a lower electrode 14 arranged below substrate 1. Upper and lower electrodes 12 and 14 are opposed to each other with substrate 1 interposed therebetween, and form a pair of the electrodes. One of upper and lower electrodes 12 and 14 is a cathode electrode, and the other is an anode electrode. Wiring (not shown) is connected to upper and lower electrodes 12 and 14, and upper and lower electrodes 12 and 14 are connected to a power supply outside plasma CVD device 10 through the wiring.

Exhaust piping 15 is arranged in a bottom portion of plasma CVD device 10. Exhaust piping 15 communicates an inner space of plasma CVD device 10 to a vacuum pump (not shown). When the vacuum pump operates, it discharges an air from the inner space of plasma CVD device 10 through exhaust piping 15 to lower an inner pressure of the vacuum container to a vacuum state. Exhaust piping 15 has a vertically extending pipe that extends vertically downward from plasma CVD device 10, and a horizontally extending pipe that extends horizontally from a bent portion at a lower end of the vertically extending pipe. Exhaust piping 15 is provided at the lower end of the vertically extending pipe with an openable and closable opening 16.

Plasma CVD device 10 is provided at a portion of its side surface with an opening 18. An openable and closable open/close door 20 is arranged for covering opening 18. When open/close door 20 opens, opening 18 opens to open plasma CVD device 10 to the atmosphere. When open/close door 20 closes, opening 18 is sealingly closed to attain a state in which the inner pressure of plasma CVD device 10 can be lowered to a vacuum.

For performing the film forming processing on substrate 1, open/close door 20 opens, and substrate 1 is placed inside plasma CVD device 10 through opening 18. Then, open/close door 20 closes to keep opening 18 in the closed state, and the air in plasma CVD device 10 is discharged through exhaust piping 15 so that the pressure of the inner space of plasma CVD device 10 decreases to attain the vacuum state. Subsequently, a gas supply unit (not shown) supplies a process gas into plasma CVD device 10. High-frequency electric power is supplied between upper and lower electrodes 12 and 14 so that the process gas between upper and lower electrodes 12 and 14 is excited to attain a plasma state. Thereby, atoms and molecules of the chemically activated process gas are brought into contact with a main surface of substrate 1 to perform the film forming processing on the main surface of substrate 1.

When the film forming processing is repeated, a film forming material adheres to the inner components and the inner wall of plasma CVD device 10. When silane is used as the process gas, a silicon-contained adhering material such as polysilane is accumulated inside plasma CVD device 10. For removing the silicon-contained adhering material, a cleaning operation is periodically performed by opening the vacuum container of plasma CVD device 10 to the atmosphere and removing the deposited polysilane. After the cleaning removed the adhering material, the film formation restarts.

As shown in FIG. 1, a humidifier 30 and a humidity sensor 32 are arranged outside plasma CVD device 10. Humidifier 30 is arranged near opening 18 of plasma CVD device 10 to humidify an atmosphere around plasma CVD device 10. Humidity sensor 32 measures a humidity of the atmosphere around plasma CVD device 10. Humidifier 30 can increase an absolute humidity of a gas by using a general vaporization, evaporation or water-spraying method. For example, humidifier 30 may be configured to perform the humidification by spraying fine mist particles from a nozzle.

When open/close door 20 and thus opening 18 open and thereby plasma CVD device 10 opens to the atmosphere for cleaning plasma CVD device 10, humidifier 30 operates to increase the absolute humidity around plasma CVD device 10. Preferably, humidifier 30 humidifies the surroundings of plasma CVD device 10 to attain the absolute humidity of 11.5 g/m³ or more.

Before open/close door 20 opens, humidifier 30 operates to attain the absolute humidity of 11.5 g/m³ or more around plasma CVD device 10. Thereby, the air of 11.5 g/m³ or more in absolute humidity flows into plasma CVD device 10 when plasma CVD device 10 opens to the atmosphere. Since the humidified air increases an amount of water on the surface of an object that is transported into plasma CVD device 10 in the cleaning process, an electric conductivity of the surface of the object increases to cause rapid leaking of electric charges. Thereby, the electrostatic potential of the object lowers to suppress generation of static electricity.

By suppressing generation of the static electricity during the cleaning, it is possible to suppress an oxidation reaction of fine powder of polysilane and the like inside plasma CVD device 10 so that heat generation can be reliably prevented to improve the safety during the cleaning operation of plasma CVD device 10. Further, by suppressing the static electricity, the adhering material inside plasma CVD device 10 can be easily removed from the side wall and the piping. Additionally, it is possible to suppress re-adhesion of the adhering material once removed from the side wall and the piping to the side wall and others. Therefore, the efficiency of the cleaning operation of plasma CVD device 10 can be improved.

Even when the fine powder of the adhering material floats through opening 18 to the outside of plasma CVD device 10 in the cleaning operation, the increased humidity in the surroundings can suppress smearing that may occur on other devices in a factory such as the transporting device and another processing device due to adhesion of the fine powder to them.

The humidity control of the ambient air of plasma CVD device 10 using humidifier 30 may be always performed, and alternatively may be performed only when plasma CVD device 10 is open to the atmosphere.

While plasma CVD device 10 is open to the atmosphere, an inert gas is supplied into the vacuum container to raise the pressure to the atmospheric pressure, and thereby an oxidizing reaction is suppressed. Preferably, in this operation, an inert gas containing moisture, and more preferably an inert gas of 11.5 g/m³ or more in absolute humidity may be supplied into the vacuum container, whereby generation of the static electricity in plasma CVD device 10 can be suppressed more reliably.

In general, when the relative humidity decreases below 50% at a room temperature of about 25° C., the charging voltage of the static electricity increases and the possibility of spark generation due to the static electricity increases. When the relative humidity at the room temperature is 50% or more, an amount of electricity dischargeable to the atmosphere exceeds an amount of electricity of an object that may be charged due to the static electricity so that the spark generation due to the static electricity can be suppressed. In this specification, therefore, a range of the absolute humidity of 11.5 g/m³ or more corresponding to the relative humidity of 50% at the atmospheric temperature of 25° C. is defined as a humidity safe region. By keeping the ambient air around plasma CVD device 10 in a range of the humidity safe region, it is possible to suppress the generation of the static electricity when plasma CVD device 10 is open to the atmosphere, and the cleaning operation can be performed safely.

The upper limit of the absolute humidity that is attained by humidifier 30 around plasma CVD device 10 is equal to the amount of saturated water vapor. The amount of saturated water vapor varies with temperature, and the upper limit of the absolute humidity is the absolute humidity attained when the relative humidity is 100% at each temperature. For example, when the ambient temperature of plasma CVD device 10 is 25° C., the upper limit of the absolute humidity is 23 g/m³. When the temperature is 30° C., the upper limit of the absolute humidity is 30 g/m³.

In the cleaning operation of plasma CVD device 10, the inside of exhaust piping 15 must also be cleaned. Exhaust piping 15 is thin, and structures such as lower electrode 14 inside plasma CVD device 10 may hinder access to it so that it is generally difficult to access the inside of exhaust piping 15 from the inner side of plasma CVD device 10. Accordingly, opening 16 is formed in exhaust piping 15 so that exhaust piping 15 can be easily accessed to open opening 16 from the outside of plasma CVD device 10 and thereby the internal cleaning of exhaust piping 15 can be efficiently performed.

FIG. 2 schematically shows a top view of a layout of a factory forming semiconductor manufacturing apparatus 100. Semiconductor manufacturing apparatus 100 includes plasma CVD device 10 already described with reference to FIG. 1 as well as another plasma CVD device 40 and devices 62, 64 and 66 that are used in steps other than the film forming processing. A transporting device 60 is arranged between plasma CVD devices 10 and 62. Transporting device 60 transports substrate 1 to be subjected to the film forming processing by plasma CVD device 10 from device 62 to plasma CVD device 10, and will transport it from plasma CVD device 10 to device 62.

Plasma CVD devices 10 and 40 are arranged in a section defined inside a factory that forms semiconductor manufacturing apparatus 100. Semiconductor manufacturing apparatus 100 includes a partition 50 that defines a space around plasma CVD devices 10 and 40. Plasma CVD devices 10 and 40 are surrounded by partition 50 having a rectangular side wall and a ceiling. Plasma CVD devices 10 and 40 are arranged in a space 70 surrounded by partition 50, and other devices 62, 64 and 66 are arranged in a space 80 outside partition 50.

Humidifier 30 that humidifies the surroundings of plasma CVD device 10 is arranged in space 70 partitioned by partition 50 and located on the side neighboring to plasma CVD device 10. Partition 50 surrounds a space that is located outside plasma CVD device 10 and near opening 18 formed in plasma CVD device 10. Humidifier 30 is arranged in space 70 that is defined by partition 50 and particularly is located on a side neighboring to opening 18. Humidifier 30 increases the humidity of the atmosphere in space 70. Partition 50 forms a small room containing plasma CVD device 10 and humidifier 30, and prevents water vapor supplied by humidifier 30 from diffusing from the inside of the above small room so that the surroundings around plasma CVD device 10 can be humidified more rapidly and more efficiently.

It is desired that partition 50 has a form surrounding plasma CVD device 10 as shown in FIG. 2, and is configured to form a substantially closed space around plasma CVD device 10, because this structure can suppress more reliably the diffusion of the water vapor from the surroundings of plasma CVD device 10. However, the structure of partition 50 is not restricted to the above. For example, a pair of partitions each having a screen-like form may be arranged on the laterally opposite sides of opening 18, respectively, and this structure can likewise and efficiently raise the absolute humidity near opening 18 of plasma CVD device 10. As described above, the partition may have any structure provided that it can appropriately flow the air humidified by humidifier 30 into plasma CVD device 10 through opening 18 when plasma CVD device 10 is open to the atmosphere.

An opening 52 is formed in a portion of partition 50, and transporting device 60 extending through opening 52 is arranged in both spaces 70 and 80. Transporting device 60 transports substrate 1 between plasma CVD device 10 and device 62. Opening 52 is large enough to prevent interference of substrate 1 with partition 50 around opening 52 during transportation of substrate 1, and is small enough to suppress diffusion of the water vapor that is supplied into space 70 by humidifier 30 into space 80.

By forming opening 52 and arranging transporting device 60 through opening 52, it becomes possible to perform automatic transportation of substrate 1 to plasma CVD device 10. By sufficiently reducing the size of opening 52, it is possible to achieve sufficiently the effect of humidifying the surroundings of plasma CVD device 10 by humidifier 30. Alternatively, a gate valve for opening and closing opening 52 may be employed to control the opening/closing of opening 52 by opening or closing the gate valve. Also, an air curtain or the like may be employed to shut off opening 52.

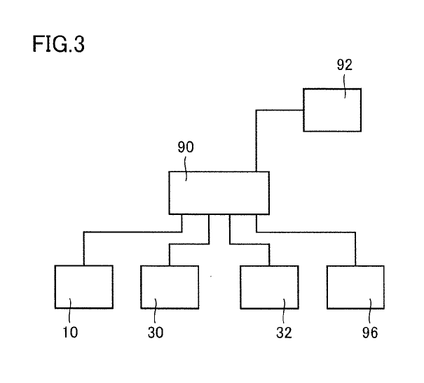

Semiconductor manufacturing apparatus 100 includes a control device shown in FIG. 3. The control device includes a control unit 90 such as a CPU (Central Processing Unit) for entirely controlling semiconductor manufacturing apparatus 100. Control unit 90 is connected via wiring to each of plasma CVD device 10, humidifier 30 and humidity sensor 32. Control unit 90 instructs the operation and stop of plasma CVD device 10 and humidifier 30. Control unit 90 receives from humidity sensor 32 a signal indicative of the absolute humidity around plasma CVD device 10 measured by humidity sensor 32.

Also, the control device includes a memory 92 for storing programs to be executed by control unit 90. Control unit 90 reads the programs stored in memory 92 and executes them to operate or stop various devices forming semiconductor manufacturing apparatus 100 such as plasma CVD device 10, humidifier 30 and the like.

Further, the control device includes an alarming unit 96. For example, alarming unit 96 has an alarm lamp, alarm buzzer or the like. When alarming unit 96 operates, it instructs an operator of semiconductor manufacturing apparatus 100 to perform operations.

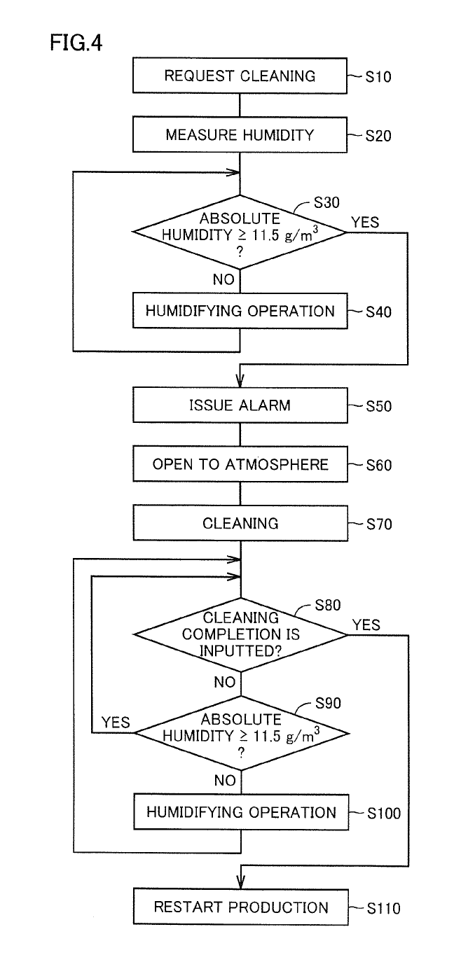

Referring to FIG. 4, description will be given about a manner of cleaning the silicon-contained adhering material such as polysilane that is deposited inside plasma CVD device 10.

First, in a step (S10), plasma CVD device 10 requests the cleaning. Whether the cleaning of plasma CVD device 10 is required or not is determined based on, e.g., a total number of times of the film forming operation. In a next step (S20), humidity sensor 32 measures the humidity of the surroundings of plasma CVD device 10. Subsequently, in a step (S30), it is determined whether the absolute humidity measured by humidity sensor 32 is equal to or higher than 11.5 g/m³ that is set as a threshold for suppressing the generation of static electricity, or not.

When it is determined in step (S30) that the absolute humidity is smaller than 11.5 g/m³, humidifier 30 operates in a next step (S40) to perform the humidifying operation that increases the humidity of the surroundings of plasma CVD device 10. The determination in step (S30) and the humidifying operation in step (S40) will be repeated until the absolute humidity of the surroundings of plasma CVD device 10 measured by humidity sensor 32 attains 11.5 g/m³ or more. While the absolute humidity is smaller than 11.5 g/m³, alarming unit 96 may be used to issue an alarm for inhibiting the opening of plasma CVD device 10 to the atmosphere.

When the surroundings of plasma CVD device 10 is humidified to attain the absolute humidity of 11.5 g/m³ or more, and it is determined in step (S30) that the absolute humidity is equal to 11.5 g/m³ or more, the opening of plasma CVD device 10 to the atmosphere is allowed. In a subsequent step (S50), alarming unit 96 issues an alarm for executing the cleaning. In response to this alarm for executing the cleaning, an operator operating semiconductor manufacturing apparatus 100 opens plasma CVD device 10 to the atmosphere in a step (S60), and starts the cleaning for removing a deposit inside plasma CVD device 10 in a step (S70).

In a next step (S80), it is determined whether the operator has inputted information of completion of the cleaning, or not. The input of the information of the cleaning completion may be performed through alarming unit 96 or plasma CVD device 10, or the information may be directly inputted to control unit 90.

When the information of the cleaning completion is not inputted, it is determined again in a subsequent step (S90) whether the absolute humidity measured by humidity sensor 32 is 11.5 g/m³ or more, or not. When it is determined in step (S90) that the absolute humidity is 11.5 g/m³ or more, the processing returns to the determination in step (S80). When it is determined in step (S90) that the absolute humidity is smaller than 11.5 g/m³, the humidifying operation is performed in a step (S100). In this manner, the control is performed to keep always the absolute humidity of the surroundings of plasma CVD device 10 at 11.5 g/m³ or more during the cleaning operation. Typically, humidifier 30 always continues its operation during the cleaning operation.

After the operator ended the cleaning and closed open/close door 20, the operator inputs the information of the cleaning completion to control unit 90. At this time, it is determined in step (S80) that the information of the cleaning completion is inputted, and the processing proceeds to a step (S110) to restart the production of the semiconductors using plasma CVD device 10. When such setting is employed that the humidity control of the air around plasma CVD device 10 using humidifier 30 is performed only when plasma CVD device 10 is open to the atmosphere, humidifier 30 stops in this step (S110).

In the cleaning method of plasma CVD device 10 that has been described, humidity sensor 32 measures the humidity of the surroundings of plasma CVD device 10, and plasma CVD device 10 opens to the atmosphere only when it is determined that the humidity is 11.5 g/m³ or more. By performing the cleaning operation in the humidity safe region where the absolute humidity is 11.5 g/m³ or more, it becomes possible to suppress generation of the static electricity during the cleaning so that the possibility of the heat generation can be removed to perform the cleaning operation more safely.

The invention can be widely used in a manufacturing process of semiconductor elements employing the plasma CVD device.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A cleaning method of a film forming device comprising the steps of:
humidifying surroundings of the film forming device;
opening said film forming device to an atmosphere; and
removing a deposit inside said film forming device.

2. The cleaning method of the film forming device according to claim 1, wherein
said step of humidifying humidifies the surroundings of said film forming device to an absolute humidity of 11.5 g/m³ or more.

3. The cleaning method of the film forming device according to claim 1, further comprising the steps of:
measuring a humidity of the surroundings of said film forming device; and
determining whether the surroundings of said film forming device have the absolute humidity of 11.5 g/m³ or more, or not, wherein
when it is determined in said step of determining that the surroundings of said film forming device have the absolute humidity smaller than 11.5 g/m³, the opening of said film forming device to the atmosphere is inhibited, and
when it is determined in said step of determining that the surroundings of said film forming device have the absolute humidity equal to 11.5 g/m³ or more, the opening of said film forming device to the atmosphere is allowed.

4. A semiconductor manufacturing apparatus comprising:
a film forming device; and
a humidifier arranged outside said film forming device for humidifying surroundings of said film forming device.

5. The semiconductor manufacturing apparatus according to claim 4, wherein
said film forming device is provided with an opening,
said semiconductor manufacturing apparatus further comprises an openable and closable open/close door capable of opening and closing said opening, and
said humidifier humidifies the surroundings of said film forming device when the open/close door opens to open said opening.

6. The semiconductor manufacturing apparatus according to claim 5, further comprising:
a partition for defining a space surrounding said film forming device, wherein
said humidifier is arranged in the space defined by said partition and is located on a side neighboring to said opening.

7. The semiconductor manufacturing apparatus according to claim 4, further comprising:
a humidity sensor for measuring a humidity of the surroundings of said film forming device.

8. The semiconductor manufacturing apparatus according to claim 4, further comprising:
a control unit for controlling an operation of said semiconductor manufacturing apparatus, wherein
said control unit operates said humidifier to humidify the surroundings of said film forming device and to attain an absolute humidity of 11.5 g/m³ or more.

9. The semiconductor manufacturing apparatus according to claim 4, further comprising:
an alarming unit for giving an operation instruction to an operator operating said semiconductor manufacturing apparatus.
